(19) United States
(12) Patent Application Publication
(10) Pub. No.: US 2014/0030881 A1
(43) Pub. Date: Jan. 30, 2014

(54) PHOTORESIST COMPOSITION, THIN FILM TRANSISTOR ARRAY PANEL, AND METHOD OF MANUFACTURING THE SAME

(71) Applicant: SAMSUNG DISPLAY CO., LTD., Yongin-City (KR)

(72) Inventors: Ki Beom LEE, Seoul (KR); Chang Hoon KIM, Asan-si (KR); Sang Hyun LEE, Yongin-si (KR); Hi Kuk LEE, Yongin-si (KR); Jae Hyuk CHANG, Seongnam-si (KR); Kab Jong SEO, Seoul (KR); Jun Ho SIM, Seoul (KR)

(73) Assignee: SAMSUNG DISPLAY CO., LTD., Yongin-City (KR)

(21) Appl. No.: 13/683,510

(22) Filed: Nov. 21, 2012

(30) Foreign Application Priority Data
Jul. 26, 2012 (KR) 10-2012-0081691

(51) Int. Cl. G03F 7/039; H01L 21/768

(52) U.S. Cl. CPC G03F 7/039; H01L 21/76838
USPC 438/586; 430/286.1

(57) ABSTRACT

A positive photoresist composition including a novolac resin, a photo active compound (PAC), a melamine crosslinking agent, and a solvent.

### CROSS-REFERENCE TO RELATED APPLICATION

This application claims priority to and the benefit of Korean Patent Application No. 10-2012-0081691 filed on Jul. 26, 2012, and all the benefits accruing therefrom under 35 U.S.C. §119, the content of which is incorporated herein in its entirety by reference.

### BACKGROUND

(a) Field

The present disclosure relates to a photoresist composition, thin film transistor array panel, and method of manufacturing the same.

(b) Description of the Related Art

In general, a flat panel display can be a liquid crystal display (LCD) or an organic light emitting diode (OLED) display.

The liquid crystal display includes two sheets of display substrates, each with a field generating electrode, and a liquid crystal layer interposed therebetween. A voltage may be applied to the electrodes to rearrange liquid crystal molecules of the liquid crystal layer, thereby controlling transmittance of light passing through the liquid crystal layer.

The liquid crystal display is manufactured by performing a series of processes such as cleaning, depositing, photolithography, and etching on a glass substrate.

Among them, a photolithography processing system is classified as a photolithography processing system using a positive photoresist and a photolithography processing system using a negative photoresist.

Here, the photolithography processing system using a positive photoresist is a system of forming a driving circuit pattern by removing an exposed portion, in which when the positive photoresist is exposed through a mask with a pattern, a polymer chain of the exposed portion is rendered more soluble.

Also, the photolithography processing system using a negative photoresist is a system of forming a driving circuit pattern by removing a non-exposed portion, in which when the negative photoresist is exposed through a mask with a pattern, a polymer of the exposed portion is made insoluble.

For exposure, an exposer is used and a photoresist suitable for the exposer is desirable. Recently, a digital exposer for forming a photoresist pattern having an improved resolution has been developed. A photoresist which is more suitable for the digital exposer would be desirable.

### SUMMARY

The following description relates to a photoresist composition which is more suitable for the digital exposer and a method of manufacturing of a thin film transistor array panel using the same.

An exemplary embodiment provides a positive photoresist composition containing a novolac resin, a photo active compound (“PAC”), a melamine crosslinking agent, and a solvent.

The photo active compound may contain 1,2-naphthoquinonediazide-5-sulfonate.

The photo active compound may be formed by condensing a quinone diazide sulfonic acid chloride containing 1,2-benzoquinone diazide-4-sulfonic acid chloride and 1,2-napthoquinone diazide-5-sulfonic acid chloride with a phenol compound containing 2,3,4-trihydroxybenzophenone and 2,2′,4,4′-tetrahydroxybenzophenone.

The novolac resin may include a high molecular weight portion, a medium molecular weight portion, and a low molecular weight portion, wherein an amount of at least one of the medium molecular weight portion or the low molecular weight portion in the novolac resin treated by a solvent may be reduced compared to the amount in the novolac resin untreated by the solvent.

The novolac resin may include at least one structural unit of ortho-cresol, meta-cresol, para-cresol, 2,3-dimethylphenol, 3,4-dimethylphenol, 3,5-dimethylphenol, 2,4-dimethylphenol, 2,6,6-trimethylphenol, 2-methylresorcinol, 4-methylresorcinol, 5-methylresorcinol, 3-propylphenol, 4-propylphenol, 2-isopropylphenol, or 2-methoxy-5-methylphenol.

The novolac resin may contain the meta-cresol and the para-cresol structural units, wherein a molar fraction of the para-cresol unit may be greater than a molar fraction of the meta-cresol unit.

The photoresist composition may form a photoresist pattern having a resolution of about 1.5 micrometers or less.

The photoresist composition may be effective to form a photoresist pattern when exposed to light of about 355 nanometers (“nm”).

The photoresist composition may be applied to a digital exposer.

The positive photoresist composition may further include a photosensitivity enhancer, and the photosensitivity enhancer may include at least one of 2,3,4,4′-tetrahydroxybenzophenone, 2,3,4-trihydroxybenzophenone, or 1-[1-(4-hydroxyphenyl)-isopropyl]-4-[1,1-bis(4-hydroxyphenyl)ethyl]benzene.

The melamine crosslinking agent may include at least one of an alkoxyalkylmelamine compound containing methoxymethylmelamine and hexamethoxymethylmelamine, an alkoxyalkylmethanolmelamine compound, or a carboxymethylmelamine compound.

The solvent may include at least one of ethyl acetate, butyl acetate, ethylene glycol monoethylether acetate, diethylene glycol monoethylether acetate, propylene glycol monoethylether acetate, acetone, methyl ethyl ketone, ethyl alcohol, methanol, propyl alcohol, isopropyl alcohol, ethylene glycol, ethyleneglycol monoethylether, or diethyleneglycol monoethylether.

Another exemplary embodiment provides a method of manufacturing of a thin film transistor array panel, including forming a pattern member material layer on a substrate; forming a photoresist on the pattern member material layer; exposing the photoresist; forming a photoresist pattern by developing the exposed photoresist; and forming a pattern member by patterning the pattern member material layer by using the photoresist pattern as a mask, in which the photoresist includes a novolac resin, a photo active compound, a melamine crosslinking agent, and a solvent.

The method of manufacturing of a thin film transistor array panel may further include forming a gate line, a data line, and a thin film transistor connected with the gate line and the data line on the substrate; forming a passivation layer on the thin film transistor; and forming a pixel electrode on the passivation layer, in which the pattern member may include at least one of the gate line or the pixel electrode.

The pixel electrode may include a slit pattern.

The photo active compound may contain 1,2-naphthoquinonediazide-5-sulfonate.

The novolac resin may include a high molecular weight portion, a medium molecular weight portion and a low molecular weight portion, wherein an amount of at least one of the medium molecular weight portion or the low molecular weight portion in the novolac resin treated by a solvent may be reduced compared to the amount in the novolac resin untreated by the solvent.

The novolac resin may contain the meta-cresol and the para-cresol structural units, and a molar fraction of the para-cresol structural unit may be greater than a molar fraction of the meta-cresol structural unit.

The photoresist may be effective to form a photoresist pattern when exposed to light of about 355 nm.

The exposing of the photoresist may include a digital exposer.

According to an exemplary embodiment, a new photoresist composition which is optimized for a new exposer is provided, and the photoresist composition can facilitate a tapered angle and improved resolution.

### BRIEF DESCRIPTION OF THE DRAWINGS

The above and other aspects, advantages and features of this disclosure will become more apparent by describing in further detail exemplary embodiments thereof with reference to the accompanying drawings, in which:

FIG. 1A is a graph of gel permeation chromatography (“GPC”) signal (arbitrary units) versus time (hours) illustrating a general molecular weight distribution as determined by gel permeation chromatography analysis of a novolac resin, and FIG. 1B is a graph of gel permeation chromatography signal (arbitrary units) versus time (hours) illustrating a molecular weight distribution as determined by GPC analysis of a novolac resin according to an exemplary embodiment;

FIG. 2A is a graph of absorbance (arbitrary units) versus light wavelength (nanometers, m) of a photoresist composition including 1,2-naphthoquinonediazide-4-sulfonate, and FIG. 2B is a graph illustrating absorbance (arbitrary units) versus light wavelength (nanometers, m) of a photoresist composition including 1,2-naphthoquinonediazide-5-sulfonate according to an exemplary embodiment;

FIGS. 3A and 3B are photographs of a Comparative Example and an Example, respectively, illustrating shapes of a photoresist pattern;

FIGS. 4A and 4B are schematic diagrams illustrating the Comparative Example and the Example, respectively, illustrating a skew;

FIG. 5 is a flowchart illustrating an exemplary embodiment of a method of manufacturing of a thin film transistor array panel using a photoresist composition;

FIG. 6 is a plan view illustrating an exemplary embodiment of a liquid crystal display;

FIG. 7 is a cross-sectional view of FIG. 6 taken along line VII-VII;

FIG. 8 is a plan view illustrating an embodiment of a pixel electrode; and

FIG. 9 is a plan view illustrating an exemplary embodiment of a basic electrode in the liquid crystal display.

### DETAILED DESCRIPTION

Hereinafter, an exemplary embodiment will be described in further detail with reference to the accompanying drawings. As those skilled in the art would realize, the described embodiments may be modified in various different ways, all without departing from the spirit or scope of the present disclosure. On the contrary, exemplary embodiments introduced herein are provided to make the disclosed contents thorough and complete to those skilled in the art.

In the drawings, the thickness of layers, films, panels, regions, etc., may be exaggerated for clarity. It will be understood that when a layer is referred to as being “on” another layer or substrate, it can be directly on that layer or an intervening layer may also be present. Like reference numerals designate like elements throughout the specification.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer, or section discussed below could be termed a second element, component, region, layer, or section without departing from the teachings of the present embodiments.

The terminology used herein is for the purpose of describing particular embodiments only and is not intended to be limiting. As used herein, the singular forms “a,” “an” and “the” are intended to include the plural forms as well, unless the context clearly indicates otherwise. The term “or” means “and/or.” It will be further understood that the terms “comprises” and/or “comprising,” “contains” and/or “containing,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to other elements as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below. Expressions such as “at least one of,” when preceding a list of elements, modify the entire list of elements and do not modify the individual elements of the list.

Unless otherwise defined, all terms (including technical and scientific terms) used herein have the same meaning as commonly understood by one of ordinary skill in the art to which this general inventive concept belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

“Alkyl” as defined herein refers to a straight or branched chain, saturated, monovalent hydrocarbon group (e.g., methyl or hexyl).

“Alkoxy” as defined herein refers to an alkyl group that is linked via an oxygen (i.e., alkyl-O—), for example methoxy, ethoxy, and sec-butyloxy groups.

“Alkoxyalkyl” as defined herein refers to an alkyl radical substituted with one or more alkoxy groups.

A photoresist composition according to an exemplary embodiment includes a novolac resin, a photo active compound (“PAC”), a melamine crosslinking agent, and a solvent. The photoresist composition according to an exemplary embodiment may be a positive photoresist.

The novolac resin according to an exemplary embodiment has excellent film formability, so a uniform film having a suitable thickness may be formed. Further, the novolac resin may be dissolved in a developer, which is an alkali aqueous solution, and may withstand a process such as a soft bake or a hard bake due to its high thermostability.

The novolac resin may be formed by a condensation reaction of a phenol or a cresol and a formaldehyde in the presence of an acid or alkali catalyst.

As a raw material for the synthesis of a novolac resin for a semiconductor photoresist, a cresol and a formaldehyde may be usually used. The cresol may include at least one of meta-cresol (m-cresol) or para-cresol (p-cresol). An example of a synthesis of a novolac resin is shown by the following Reaction Scheme (1).

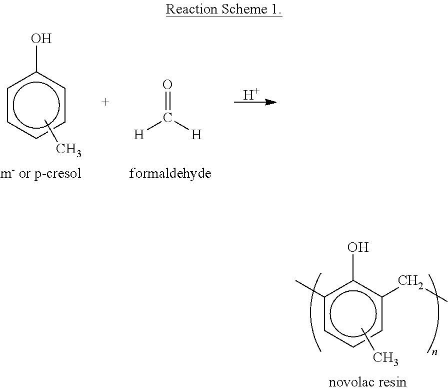

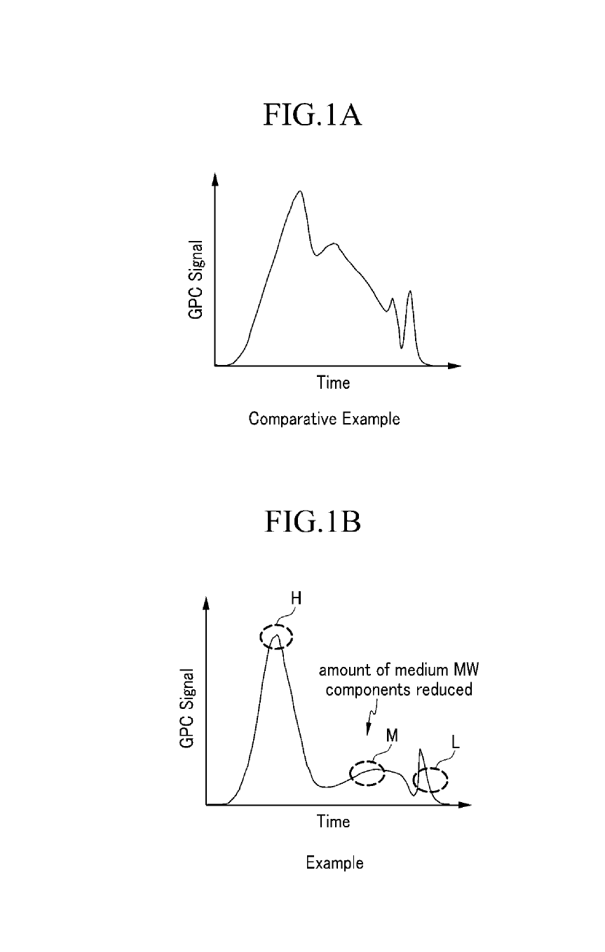

FIG. 1A is a graph illustrating a molecular weight distribution when determined by gel permeation chromatography (“GPC”) analysis of a novolac resin, and FIG. 1B is a graph illustrating a molecular weight distribution when determined by the GPC analysis of a novolac resin according to an exemplary embodiment.

The novolac resin according to an exemplary embodiment includes a high molecular weight portion, a medium molecular weight portion, and a low molecular weight portion. Here, the high molecular weight portion has an average molecular weight of approximately 5,000 to 30,000 Daltons (“Da”), the medium molecular weight portion has an average molecular weight of approximately 2,000 to 5,000 Da, and the low molecular weight portion has an average molecular weight of approximately 50 to 2,000 Da.

Referring to FIG. 1A, generally, all three molecular weight portions of the novolac resin are evenly distributed. FIG. 1A illustrates Comparative Example.

In an exemplary embodiment, the novolac resin is treated with a solvent after synthesizing and an amount of at least one of the medium molecular weight portion or the low molecular weight portion may be reduced. Referring to FIG. 1B, in the novolac resin according to an exemplary embodiment, it is determined that a high molecular weight region H is relatively wide compared to a medium molecular weight distribution region M and a low molecular distribution region L. While not wanting to be bound by theory, it is understood that components included in the medium molecular weight distribution region and a low molecular weight distribution region are more susceptible to heat that those of a high molecular weight distribution region, and thermal degradation may result in deterioration of a tapered portion of the photoresist pattern. However, since a component of the novolac resin corresponding to the high molecular distribution region is comparatively stable to heat, a stability of the tapered portion of the photoresist pattern may be improved when a novolac resin having a reduced amount of a medium molecular weight portion or a low molecular weight portion is used. Accordingly, the photoresist composition according to an exemplary embodiment provides improved pattern resolution.

Here, the solvent treatment results in reduction of an amount of the medium molecular weight portion and the low molecular weight portion. The reduction may occur through volatilization, dissolution, and the like. A suitable solvent may include propylene glycol monomethyl ether acetate (“PGMEA”), ethanol, methanol, butyl acetate, butyl cellosolve, propylene carbonate, and the like.

Resolution of the photoresist pattern may be improved by reducing the amount of the medium molecular weight portion or the low molecular weight portion of the novolac resin as described above. Resolution of photoresist pattern may also be improved by using a novolac resin containing an increased mole fraction of the para-cresol structural unit, which has slow reactivity. Thus, it may be desirable to use a higher mole fraction of the para-cresol structural unit, which has slow reactivity, as compared to a mole fraction of the meta-cresol structural unit. Also, an amount of the solvent treatment may be selected.

The novolac resin according to an exemplary embodiment may include at least one structural unit of ortho-cresol, meta-cresol, para-cresol, 2,3-dimethylphenol, 3,4-dimethylphenol, 3,5-dimethylphenol, 2,4-dimethylphenol, 2,6,6-trimethylphenol, 2-methylresorcinol, 4-methylresorcinol, 5-methylresorcinol, 3-propylphenol, 4-propylphenol, 2-isopropylphenol, or 2-methoxy-5-methylphenol.

Cresol, which is the raw material of the novolac resin, is a phenol molecule which contains a methyl substituted benzene ring. While not wanting to be bound by theory, it is understood that when an —OH group of the phenol is in the 1-position, due to a unique chemical property of the —OH group, the 2,4, and 6-positions of the benzene ring are activated, and as a result, a reactivity of the phenol ring is increased. The cresol may contain the isomers ortho-cresol, meta-cresol, and para-cresol, as shown in the following Chemical Formula (1), Chemical Formula (2), and Chemical Formula (3).

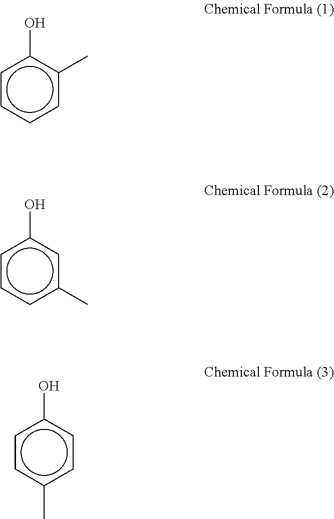

While not wanting to be bound by theory, it is understood that the para-cresol may have weaker reactivity than the meta-cresol because the 4-position of the benzene ring in para-cresol is blocked by a methyl group. The reactivity of para-cresol is approximately 8 times lower than the reactivity of the meta-cresol. Therefore, the novolac resin formed from meta-cresol and para-cresol may be referred to as a block copolymer. Due to a significant difference in a reactivity of meta-cresol and para-cresol, a polymer blend, in which a high molecular weight portion and a medium molecular weight portion of the novolac resin are composed of a meta-cresol structural unit, and in which the low molecular weight portion is composed of para-cresol structural unit, may be formed. Meta-cresol and para-cresol structural units of the novolac resin are shown by the following Chemical Formulas (4) and (5), respectively:

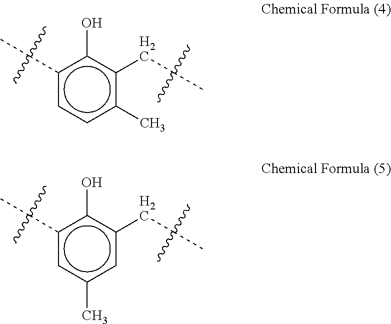

In an exemplary embodiment, the novolac resin may contain the meta-cresol and the para-cresol structural units, and a mole fraction of the para-cresol structural unit may be larger than a mole fraction of the meta-cresol structural unit.

In order to improve a resolution of a photoresist pattern, a tapered angle of the photoresist may be evaluated. Also, since light is diffracted and scattered at an end of a mask pattern during exposure, some light is transferred even in a non-exposure region. As a result, a portion of the non-exposure region may be dissolved during developing. Accordingly, the tapered angle may be deteriorated, e.g., reduced. In order to solve the problem of reduced tapered angle, in an exemplary embodiment, a novolac resin containing an increased mole fraction of para-cresol structural units, which have slower reactivity than meta-cresol structural units, may be used. A sensitivity of the photoresist using an increased amount of para-cresol may be decreased, and the non-exposure region is not developed by slight exposure, thereby improving the tapered angle. In an embodiment, a mole ration of meta-cresol to para-cresol may be about 0.1 to about 0.9, specifically about 0.2 to about 0.8. In an exemplary embodiment, a mole ratio of meta-cresol to para-cresol may be 4:6 or more.

A photo active compound according to an exemplary embodiment is a component which is converted by light into another material. The photo active compound may be formed by reaction of a naphthoquinone diazide (“NQD”) and a polyhydroxy compound. Polyhydroxy benzophenones are widely used among polyhydroxy compounds, wherein benzophenone is a compound containing a carbonyl group between two benzene rings. The photo active compound is formed by forming an ester bond when chloride (—Cl) of the naphthoquinone diazide (NQD) and an —OH group of the polyhydroxy compound react with each other to produce hydrogen chloride (HCl). The polyhydroxy compound is used for increasing sensitivity by adding a naphthoquinone diazide to a photo active compound molecule and for serving as a dissolution inhibitor.

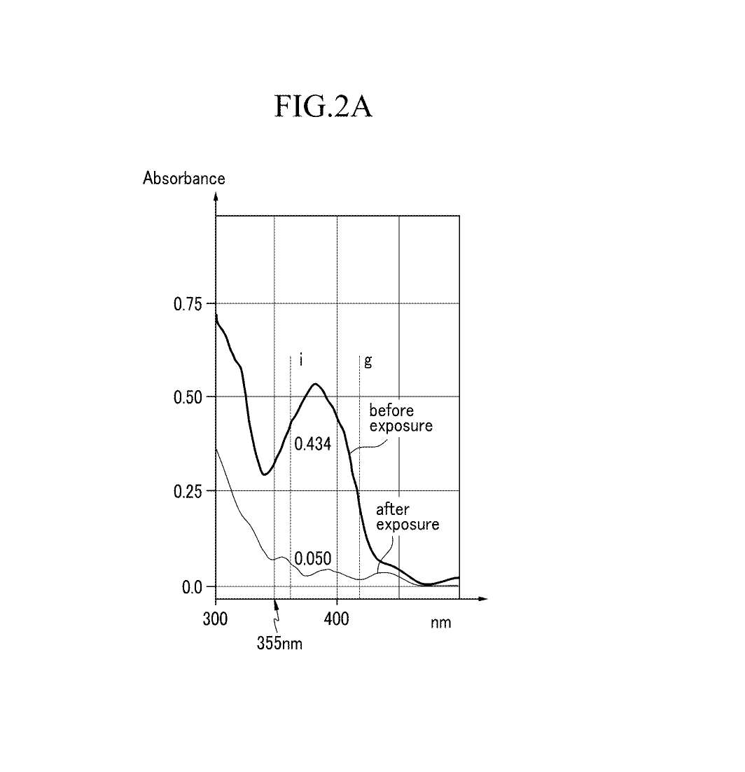

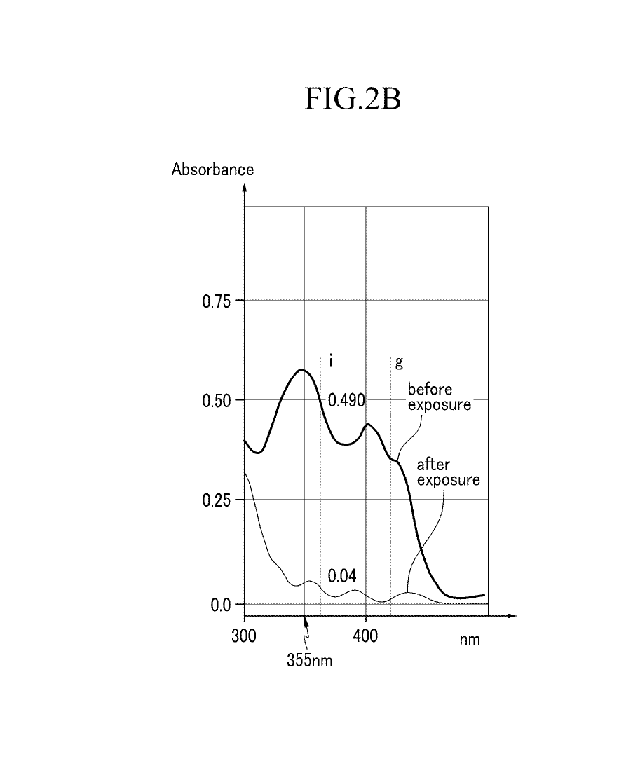

FIG. 2A is a graph illustrating absorbance versus wavelength for a photoresist composition including 1,2-naphthoquinonediazide-4-sulfonate, and FIG. 2B is a graph illustrating absorbance according to a light wavelength in a photoresist composition including 1,2-naphthoquinonediazide-5-sulfonate according to an exemplary embodiment.

Referring to FIG. 2A, in the embodiment of a photoresist composition containing 1,2-naphthoquinonediazide-4-sulfonate as a photo active compound, at a wavelength of 355 nanometers (“nm”), it is determined that absorbance before exposure is relatively small, that is, less than 0.3, and that the light is slightly absorbed even after exposure.

However, referring to FIG. 2B, when the photo active compound contained in the photoresist composition contains 1,2-naphthoquinonediazide-5-sulfonate, at the wavelength of about 355 nm, it is determined that absorbance before exposure is higher, that is, 0.50 or more, and the light is almost completely absorbed after exposure. Accordingly, when the photoresist composition according to an exemplary embodiment is used, light absorbance at the wavelength of about 355 nm is improved.

The photo active compound according to an exemplary embodiment may be formed by condensing a quinone diazide sulfonic acid chloride containing 1,2-benzoquinone diazide-4-sulfonic acid chloride and 1,2-napthoquinone diazide-5-sulfonic acid chloride with a phenol compound containing 2,3,4-trihydroxybenzophenone and 2,2′,4,4′-tetrahydroxybenzophenone.

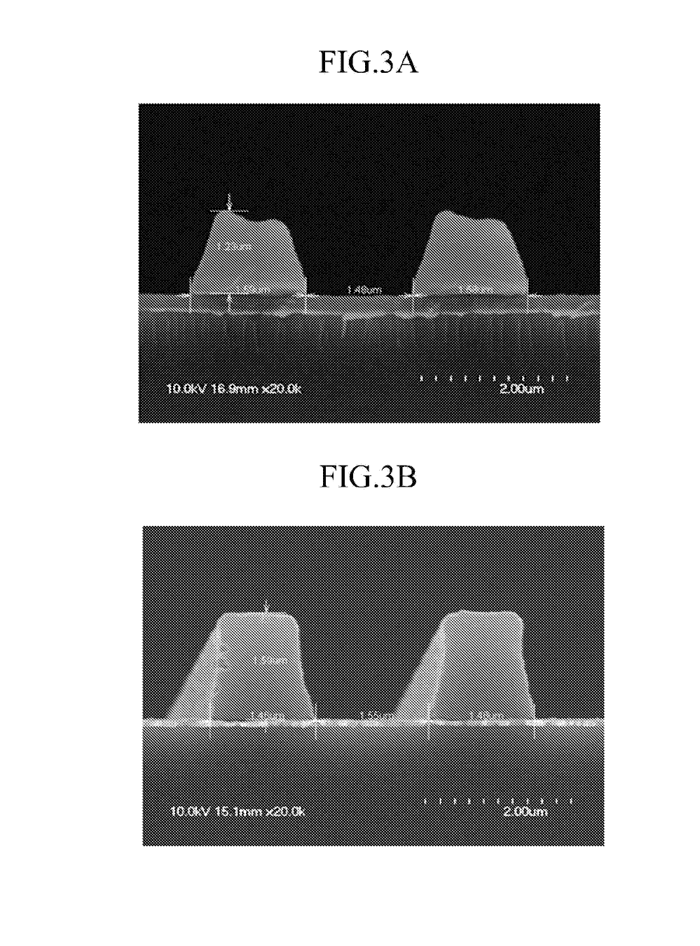

FIGS. 3A and 3B are photographs of photoresist patterns of the Comparative Example and the Example illustrating shapes of a photoresist pattern.

Referring to FIG. 3A, in the case of the Comparative Example, top loss of a pattern is shown. In general, where an amount of the novolac resin is the same, when a an amount of a photo active compound is increased, a contrast ratio and CD linearity, which illustrates a degree to which a developed pattern of the photoresist is the same as a size of a pattern of a mask, are improved. Also, a photo speed is decreased. While not wanting to be bound by theory, it is understood that the reason is that the presence of the photo active compound in the composition diminishes the alkali solubility of the novolac resin. In an exemplary embodiment shown in FIG. 3B, the top loss of the pattern may be reduced by using the polyhydroxy compound, which has a strong dissolution inhibiting property.

The photoresist composition according to an exemplary embodiment may include an additive such as a surfactant, a melamine crosslinking agent, and the like.

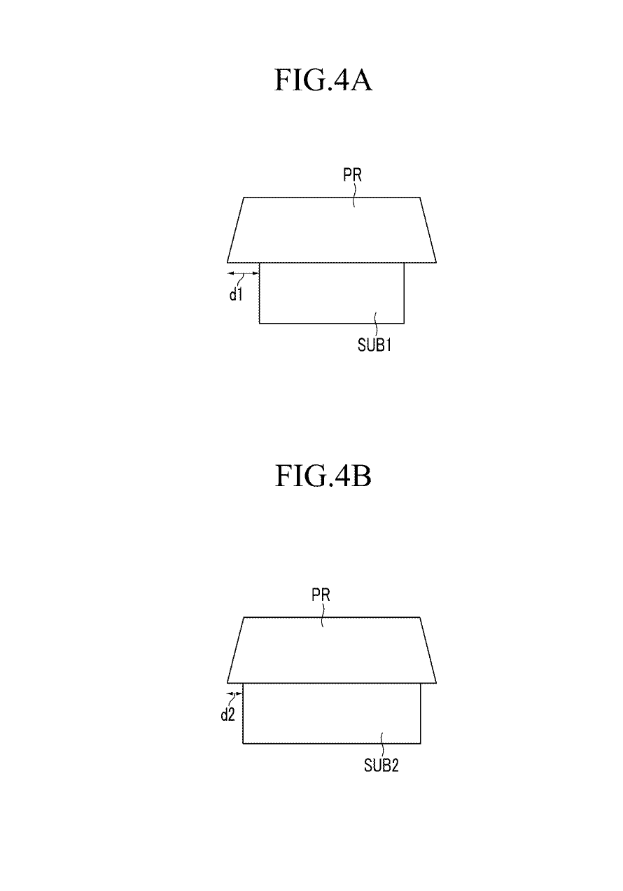

FIGS. 4A and 4B are schematic diagrams illustrating a Comparative Example and an Example illustrating a skew.

Referring to FIG. 4A in the Comparative Example, wherein a skew below a photoresist pattern PR which does not use a melamine crosslinking agent represents a first width d1. The photoresist composition according to an exemplary embodiment contains the melamine crosslinking agent as an additive to increase adhesion to a substrate SUB2, which is a target object to be patterned, thereby reducing an etch skew. FIG. 4B illustrates an etch skew when using the photoresist composition according to an exemplary embodiment. As shown in FIG. 4B, in which the skew is a second width d2, the skew is reduced as compared with the first width d1.

The melamine crosslinking agent contained in the photoresist composition according to an exemplary embodiment may serve to reduce the etch skew.

The melamine crosslinking agent according to an exemplary embodiment may be one of an alkoxyalkylmelamine compound containing methoxymethylmelamine and hexamethoxymethylmelamine, an alkoxyalkylmethanolmelamine compound, and a carboxymethylmelamine compound.

The photoresist composition according to an exemplary embodiment may further include a photosensitivity enhancer, and the photosensitivity enhancer according to an exemplary embodiment may include at least one selected from 2,3,4,4′-tetrahydroxybenzophenone, 2,3,4-trihydroxybenzophenone, or 1-[1-(4-hydroxyphenyl)-isopropyl]-4-[1,1-bis(4-hydroxyphenyl)ethyl]benzene.

A solvent contained in the photoresist composition according to an exemplary embodiment can dissolve the photo active compound and the novolac resin, which are components of the photoresist, to mix the dissolved photo active compound and the novolac resin and assist in forming a uniform film by a method such as spin coating. Accordingly, the solvent desirably has an ability to dissolve the photo active compound and the novolac resin without causing subsequent precipitation. Further, in an exemplary embodiment, for the film to be suitably formed the solvent should not rapidly evaporate, nor should it be difficult to remove the solvent because of its high boiling point.

The solvent may comprise an acetate, a ketone, an alcohol, or an ether. The solvent according to an exemplary embodiment may include at least one of ethyl acetate, butyl acetate, ethylene glycol monoethylether acetate, diethylene glycol monoethylether acetate, propylene glycol monoethylether acetate, acetone, methyl ethyl ketone, ethyl alcohol, methanol, propyl alcohol, isopropyl alcohol, ethylene glycol, ethyleneglycol monoethylether, or diethyleneglycol monoethylether.

A digital exposer for forming a photoresist pattern without a mask has been developed, and a photoresist more suitable for the digital exposer would be desirable. Existing exposers may include an exposer generating light of an i-line (365 nm wavelength), an exposer generating light of an h-line (405 nm wavelength), and an exposer generating light of a g-line (415 nm wavelength). However, the photoresist composition according to an exemplary embodiment may be suitable for an exposer emitting light of 355 nm wavelength. Further, the exposer may be used for forming a photoresist pattern having a pitch of 1.5 micrometer (“μm”) or less. In addition, the photoresist composition according to an exemplary embodiment may be applied to the digital exposer.

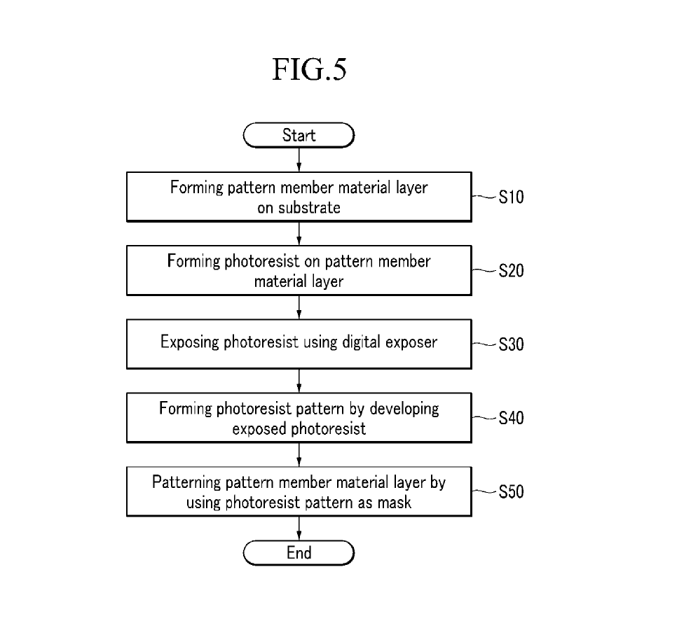

FIG. 5 is a flowchart illustrating a method of manufacturing of a thin film transistor array panel using a photoresist composition according to an exemplary embodiment.

Referring to FIG. 5, a method of manufacturing of a thin film transistor array panel according to an exemplary embodiment may form a gate line, and a data line, and a thin film transistor electrically connected thereto on a substrate. A passivation layer may be formed on the thin film transistor, and a pixel electrode may be formed on the passivation layer. The pixel electrode may be formed using a slit pattern. In this case, the gate line, the pixel electrode and the like may be formed by the following method.

First, the method includes forming a pattern member material layer on the substrate (S10).

The pattern member material layer is a target material to be patterned through a photo process, and may be a metallic material or indium tin oxide (“ITO”), indium zinc oxide (“IZO”), and the like.

Next, the method includes forming a photoresist on the pattern member material layer (S20).

The photoresist is formed by the photoresist composition according to an exemplary embodiment described above.

Next, the method includes exposing the photoresist using a digital exposer (530).

The digital exposer may generate light of 355 nm wavelength and irradiate the light to the photoresist.

Next, the method includes forming a photoresist pattern by developing the exposed photoresist (S40).

When the exposed photoresist is developed, the photoresist region receiving the light may be removed.

Next, the method includes patterning a pattern member material layer by using the photoresist pattern as a mask (550).

A pattern member is formed by patterning the pattern member material layer, and the pattern member may be the gate line and the pixel electrode described above.

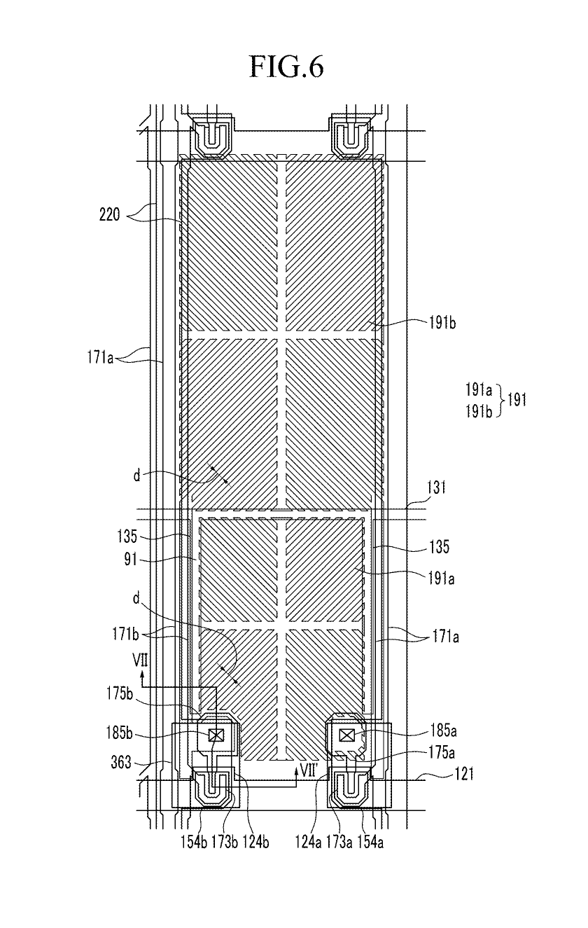

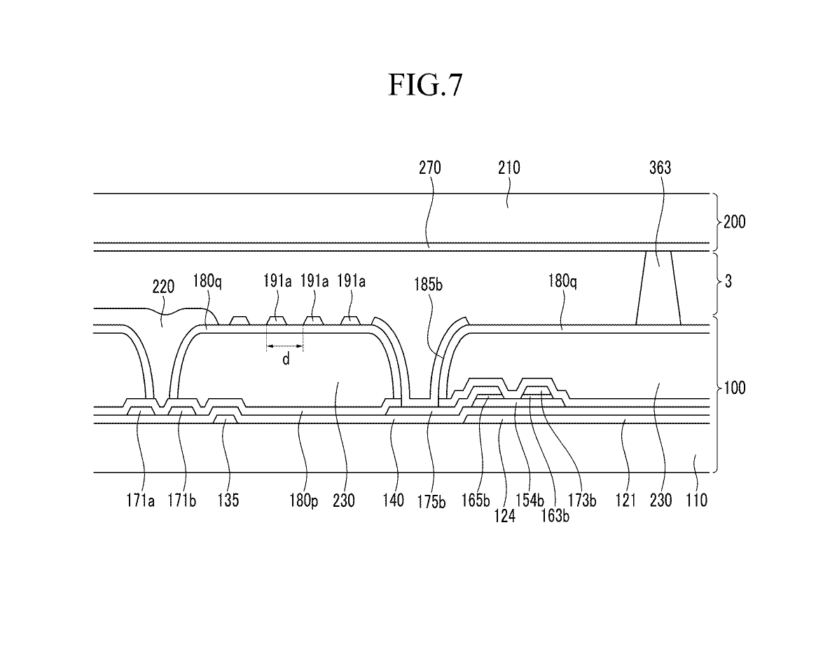

FIG. 6 is a plan view illustrating a liquid crystal display according to an exemplary embodiment. FIG. 7 is a cross-sectional view of FIG. 6 taken along line VII-VII.

Referring to FIGS. 6 and 7, a liquid crystal display according to an exemplary embodiment includes a lower panel 100 and an upper panel 200 which face each other and a liquid crystal layer 3 interposed between the two panels 100 and 200.

First, the lower panel 100 will be described.

A plurality of gate lines 121 and a plurality of storage electrode lines 131 and 135 are formed on an insulation substrate 110. Each of the gate lines includes a gate electrode 124.

The gate lines 121 transfer gate signals and mainly extend in a horizontal direction. Each gate line 121 includes a plurality of first and second gate electrodes 124a and 124b which protrude upwards. The storage electrode line includes a stem line 131 which extends substantially in parallel with the gate line 121 and a plurality of storage electrodes 135 which is stretched therefrom. Shapes and a layout of the storage electrode lines 131 and 135 may be modified in various forms. The photoresist composition according to an exemplary embodiment described above may be used in a patterning process in order to form the gate lines 121 and the storage electrode lines 131 and 135.

A gate insulating layer 140 is formed on the gate line 121 and the storage electrode lines 131 and 135, and a plurality of semiconductors 154a and 154b made of amorphous or crystalline silicon and the like is formed on the gate insulating layer 140.

A plurality of pairs of ohmic contacts 163b and 165b are formed on the semiconductors 154a and 154b, respectively, and the ohmic contacts 163b and 165b may be made of a material such as n+ hydrogenated amorphous silicon in which silicide or an n-type impurity is doped at high concentration.

A plurality of pairs of data lines 171a and 171b and a plurality of pairs of first and second drain electrodes 175a and 175b are formed on the ohmic contacts 163b and 165b and the gate insulating layer 140.

The data lines 171a and 171b transfer data signals and mainly extend in a vertical direction to cross the gate line 121 and the stem line 131 of the storage electrode line. The data lines 171a and 171b include first and second source electrodes 173a and 173b which extend toward the first and second gate electrodes 124a and 124b to be curved in a U-lettered form, and the first and second source electrodes 173a and 173b face the first and second drain electrodes 175a and 175b based on the first and second gate electrodes 124a and 124b.

The first and second drain electrodes 175a and 175b extend upwards from one end of which a part is surrounded by the first and second source electrodes 173a and 173b, respectively, and an area of the other end may be increased for connection with other layers.

However, shapes and layouts of the date lines 171a and 171b in addition to the first and second drain electrodes 175a and 175b may be modified in various forms.

The first and second gate electrodes 124a and 124b, the first and second source electrodes 173a and 173b, and the first and second drain electrodes 175a and 175b form first and second thin film transistors Qa and Qb together with the first and second semiconductors 154a and 154b, and channels of the first and second thin film transistors Qa and Qb are formed in the first and second semiconductors 154a and 154b between the first and second source electrodes 173a and 173b and the first and second drain electrodes 175a and 175b.

The ohmic contacts 163b and 165b exist only between the semiconductors 154a and 154b therebelow and the data lines 171a and 171b and drain electrodes 175a and 175b thereabove and lowers contact resistance therebetween. Exposed portions which are not covered by the data lines 171a and 171b and the drain electrodes 175a and 175b in addition to a space between the source electrodes 173a and 173b and the drain electrodes 175a and 175b exist in the semiconductors 154a and 154b.

A lower passivation layer 180p made of silicon nitride or silicon oxide is formed on the data line 171a and 171b, the drain electrodes 175a and 175b, and the exposed portions of the semiconductors 154a and 154b.

A color filter 230 and an upper passivation layer 180q are formed on the lower passivation layer 180p.

A plurality of contact holes 185a and 185b exposing the first and second drain electrodes 175a and 175b is formed on the upper passivation layer 180q. A plurality of pixel electrodes 191 is formed on the upper passivation layer 180q. The pixel electrode 191 may be made of a transparent conductive material such as ITO or IZO.

Each pixel electrode 191 includes first and second subpixel electrodes 191a and 191b which are separated from each other with a gap 91 therebetween, and the first and second subpixel electrodes 191a and 191b includes one or more basic electrodes 199 (shown in FIG. 9) or modified electrodes thereof as shown in FIGS. 4A and 4B, respectively.

A light blocking member 220 may be formed along the data line 171 or the gate line 121.

The upper panel 200 includes an insulation substrate 210 and a common electrode 270 below the insulation substrate 210.

A spacer 363 may form a gap between the lower panel 100 and the upper panel 200.

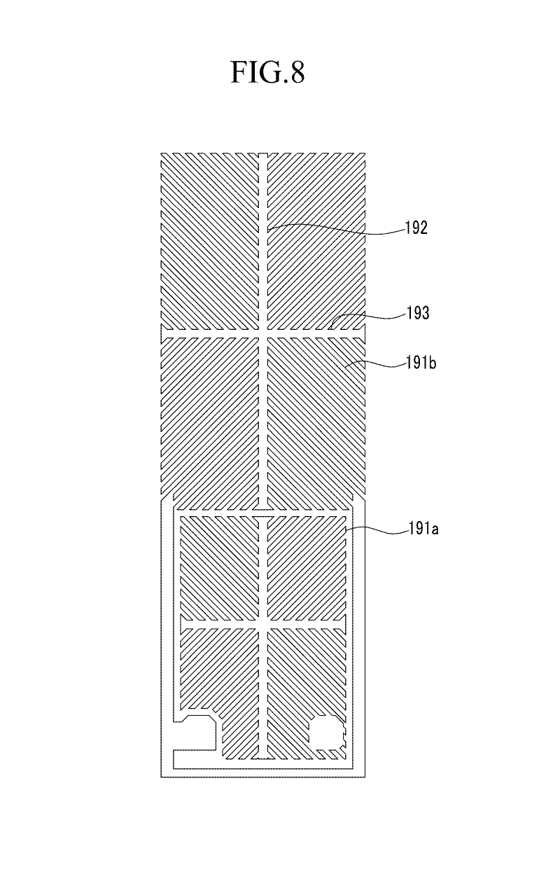

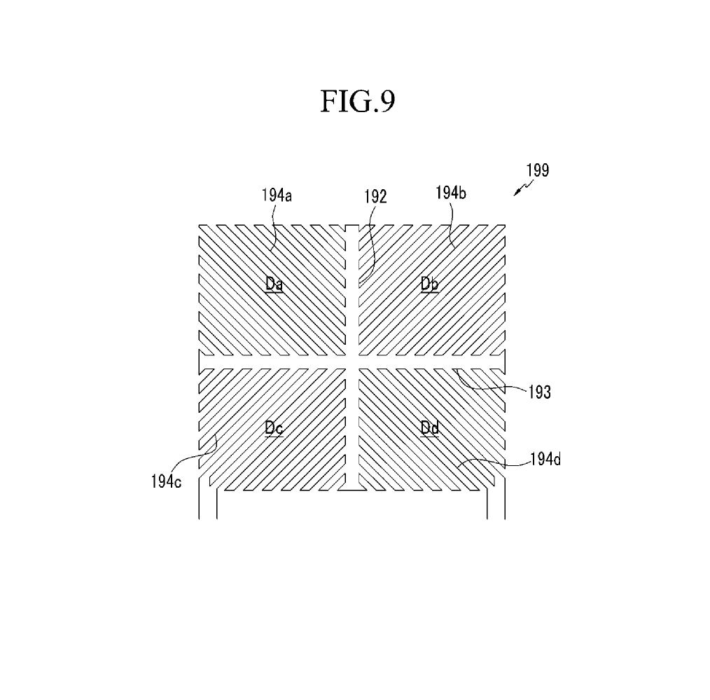

FIG. 8 is a plan view illustrating a pixel electrode. FIG. 9 is a plan view illustrating a basic electrode in the liquid crystal display according to an exemplary embodiment.

Referring to FIGS. 8 and 9, an overall shape of the basic electrode 199 is a quadrangle, the basic electrode 199 configured of a cross stem including a horizontal stem 193 and a vertical stem 192 which is perpendicular thereto. Further, the basic electrode 199 is divided into a first subregion Da, a second subregion Db, a third subregion Dc, and a fourth subregion Dd by the horizontal stem 193 and the vertical stem 192, and each subregion Da-Dd includes a plurality of first to fourth branches 194a, 194b, 194c, and 194d.

The first branch 194a obliquely extends in an upper left direction form the horizontal stem 193 or the vertical stem 192, and the second branch 194b obliquely extends in an upper right direction form the horizontal stem 193 or the vertical stem 192. Further, the third branch 194c obliquely extends in a lower left direction form the horizontal stem 193 or the vertical stem 192, and the fourth branch 194d obliquely extends in a lower right direction form the horizontal stem 193 or the vertical stem 192.

The first to fourth branches 194a-194d form an angle of about 45 degrees or 135 degrees with the gate line 121 or the horizontal stem 193. The branches 194a-194d of the two adjacent subregions Da-Dd may be perpendicular to each other.

Although not shown, a width of the branches 194a-194d may be increased as the branches are closer to the horizontal stem 193 or the vertical stem 192.

As described above, the pixel electrode 191 has the photoresist pattern. A width d of the branches 194a-194d included in the pixel electrodes 191a and 191b shown in FIGS. 2 and 3 may be 1 μm to 4 μm.

In order to form the pixel electrode 191 by the photoresist pattern, the photoresist composition according to an exemplary embodiment may be used.

In detail, referring back to FIGS. 6 and 7, a transparent conductive film such as indium tin oxide (ITO) and indium zinc oxide (IZO) is formed on the upper passivation layer 180q.

Next, the positive photoresist according to an exemplary embodiment described above is coated on the transparent conductive film. Next, the photoresist is exposed and developed by using a mask to form a photoresist pattern. Next, the pixel electrode 191a is formed by using the photoresist pattern as an etching mask.

The pixel electrode pattern may be formed by using the photoresist composition according to an exemplary embodiment.

The photoresist composition according to an exemplary embodiment may be applied in the case of forming the pixel electrode in an organic light emitting diode display.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A positive photoresist composition, comprising:
a novolac resin,
a photo active compound,
a melamine crosslinking agent, and
a solvent.

2. The positive photoresist composition of claim 1, wherein the photo active compound comprises 1,2-naphthoquinonediazide-5-sulfonate.

3. The positive photoresist composition of claim 2, wherein the photo active compound is a product of condensing a quinone diazide sulfonic acid chloride comprising 1,2-benzoquinone diazide-4-sulfonic acid chloride and 1,2-napthoquinone diazide-5-sulfonic acid chloride with a phenol compound comprising 2,3,4-trihydroxybenzophenone and 2,2′,4,4′-tetrahydroxybenzophenone.

4. The positive photoresist composition of claim 1, wherein the novolac resin includes a high molecular weight portion, a medium molecular weight portion and a low molecular weight portion, and
wherein an amount of at least one of the medium molecular weight portion or the low molecular weight portion of the novolac resin is reduced compared to an amount of a medium molecular weight portion or the low molecular weight portion in a same novolac resin not treated by a solvent.

5. The positive photoresist composition of claim 1, wherein the novolac resin comprises at least one structural unit of ortho-cresol, meta-cresol, para-cresol, 2,3-dimethylphenol, 3,4-dimethylphenol, 3,5-dimethylphenol, 2,4-dimethylphenol, 2,6,6-trimethylphenol, 2-methylresorcinol, 4-methylresorcinol, 5-methylresorcinol, 3-propylphenol, 4-propylphenol, 2-isopropylphenol, or 2-methoxy-5-methylphenol.

6. The positive photoresist composition of claim 5, wherein the novolac resin comprises the meta-cresol and the para-cresol structural units, and wherein a mole fraction of the para-cresol structural unit is greater than a mole fraction of the meta-cresol structural unit.

7. The positive photoresist composition of claim 1, wherein the photoresist composition forms a photoresist pattern having a resolution of about 1.5 micrometers or less.

8. The positive photoresist composition of claim 1, wherein the photoresist composition forms a photoresist pattern when exposed to light having a wavelength of about 355 nanometers.

9. The positive photoresist composition of claim 1, wherein the photoresist composition is used for a digital exposer.

10. The positive photoresist composition of claim 1, further comprising a photosensitivity enhancer, wherein the photosensitivity enhancer comprises at least one of 2,3,4,4′-tetrahydroxybenzophenone, 2,3,4-trihydroxybenzophenone, or 1-[1-(4-hydroxyphenyl)-isopropyl]-4-[1,1-bis(4-hydroxyphenyl)ethyl]benzene.

11. The positive photoresist composition of claim 1, wherein the melamine crosslinking agent comprises at least one of an alkoxyalkylmelamine compound comprising methoxymethylmelamine and hexamethoxymethylmelamine, an alkoxyalkylmethanolmelamine compound, or a carboxymethylmelamine compound.

12. The positive photoresist composition of claim 1, wherein the solvent comprises at least one of ethyl acetate, butyl acetate, ethylene glycol monoethylether acetate, diethylene glycol monoethylether acetate, propylene glycol monoethylether acetate, acetone, methyl ethyl ketone, ethyl alcohol, methanol, propyl alcohol, isopropyl alcohol, ethylene glycol, ethyleneglycol monoethylether, or diethyleneglycol monoethylether.

13. A method of manufacturing a thin film transistor array panel comprising:
forming a pattern member material layer on a substrate;
forming a photoresist on the pattern member material layer;
exposing the photoresist;
forming a photoresist pattern by developing the exposed photoresist; and
forming a pattern member by patterning the pattern member material layer by using the photoresist pattern as a mask,
wherein the photoresist comprises a novolac resin, a photo active compound, a melamine crosslinking agent, and a solvent.

14. The method of manufacturing of a thin film transistor array panel of claim 13, further comprising:
forming a gate line, a data line, and a thin film transistor connected with the gate line and the data line on the substrate;
forming a passivation layer on the thin film transistor; and
forming a pixel electrode on the passivation layer,
wherein the pattern member includes at least one of the gate line or the pixel electrode.

15. The method of manufacturing of a thin film transistor array panel of claim 14, wherein the pixel electrode comprises a slit pattern.

16. The method of manufacturing of a thin film transistor array panel of claim 13, wherein the photo active compound comprises 1,2-naphthoquinonediazide-5-sulfonate.

17. The method of manufacturing of a thin film transistor array panel of claim 13, wherein the novolac resin comprises a high molecular weight portion, a medium molecular weight portion and a low molecular weight portion, and
wherein an amount of at least one of the medium molecular weight portion or the low molecular weight portion of the novolac resin is reduced compared to an amount of a medium molecular weight portion or the low molecular weight portion in a same novolac resin not treated by a solvent.

18. The method of manufacturing of a thin film transistor array panel of claim 13, wherein the novolac resin comprises a meta-cresol structural unit and a para-cresol structural unit, and a mole fraction of the para-cresol structural unit is larger than a mole fraction of the meta-cresol structural unit.

19. The method of manufacturing of a thin film transistor array panel of claim 13, wherein the photoresist forms the photoresist pattern when exposed to light having a wavelength of about 355 nanometers.

20. The method of manufacturing of a thin film transistor array panel of claim 13, wherein the exposing of the photoresist comprises exposing with a digital exposer.
